(19) United States
(12) Patent Application Publication
(10) Pub. No.: US 2021/0200920 A1
(43) Pub. Date: Jul. 1, 2021

(54) THREE-DIMENSIONAL SURFACE NORMAL DETERMINATION

(71) Applicant: HEWLETT-PACKARD DEVELOPMENT COMPANY, L.P., Spring, TX (US)

(72) Inventors: Matthew A. SHEPHERD, Vancouver, WA (US); Vanessa VERZWYVELT, Vancouver, WA (US)

(73) Assignee: HEWLETT-PACKARD DEVELOPMENT COMPANY, L.P., Houston, TX (US)

(21) Appl. No.: 16/076,214

(22) PCT Filed: Jul. 19, 2017
(86) PCT No.: PCT/US2017/042899

§ 371 Date: Aug. 7, 2018

(51) Int. Cl. G06F 30/23; B29C 64/393; G06F 30/17

(52) U.S. Cl. CPC G06F 30/23; B33Y 50/02; G06F 30/17; B29C 64/393

(57) ABSTRACT

An example system includes a three-dimensional (3D) print engine to produce a 3D object based on voxel data associated with the 3D object and a 3D print controller to control operation of the 3D print engine. The 3D print controller having a surface normal determination portion. The surface normal determination portion is to determine a normal for at least one surface voxel of the 3D object, the determination of the normal being based on the voxel data. The 3D print controller is to cause the 3D print engine to adjust at least one print parameter based on the normal for the at least one surface voxel determined by the surface normal determination portion.

### BACKGROUND

Three-dimensional (3D) printing is becoming ubiquitous in a variety of environments. For example, many manufacturing arrangements regularly utilize 3D printing to manufacture or facilitate the manufacturing of various components.

### BRIEF DESCRIPTION OF THE DRAWINGS

For a more complete understanding of various examples, reference is now made to the following description taken in connection with the accompanying drawings in which:

FIG. 1 illustrates an example system with determination of surface normal in a three-dimensional (3D) object;

FIG. 2 illustrates an example 3D object with a surface normal indicated;

FIG. 3 illustrates in detail a voxel representation of the highlighted portion of the example 3D object of FIG. 2;

FIG. 4 illustrates a surface voxel and an example neighborhood of the surface voxel in the voxel representation of FIG. 3;

FIG. 5 illustrates a detailed representation of the surface voxel and the example neighborhood of the surface voxel of FIG. 4;

FIG. 6 illustrates the example neighborhood of the surface voxel of FIG. 4 divided into example sub-neighborhoods;

FIG. 7 is a flow chart illustrating an example method for determining a surface normal from voxel data;

FIG. 8 is a flow chart illustrating another example method for determining a surface normal from voxel data; and

FIG. 9 illustrates a block diagram of an example system with a computer-readable storage medium including instructions executable by a processor for surface normal determination.

### DETAILED DESCRIPTION

Various examples described herein relate to three-dimensional (3D) printing. In various examples, a normal vector of the surface of the 3D object to be printed is determined based on voxel data associated with the 3D object. In various examples, a normal vector refers to the direction of a vector that is normal to a surface, such as a flat or contoured surface. The determined normal may be used to adjust at least one print parameter. For example, agents used for the surface voxel (e.g., agents with different color or thermal properties) may be adjusted to compensate for variations in the 3D print engine that may affect various properties (e.g., color) of the surface at various normal vectors. In various examples, the surface normal may be determined based on the voxel data without additional information. In this regard, a look-up table may be generated for a surface voxel. The look-up table may include values of a parameter of voxels around the surface voxel. For example, the look-up table may indicate whether a surrounding voxel exists or not. The look-up table may be used to determine a surface normal for the surface voxel.

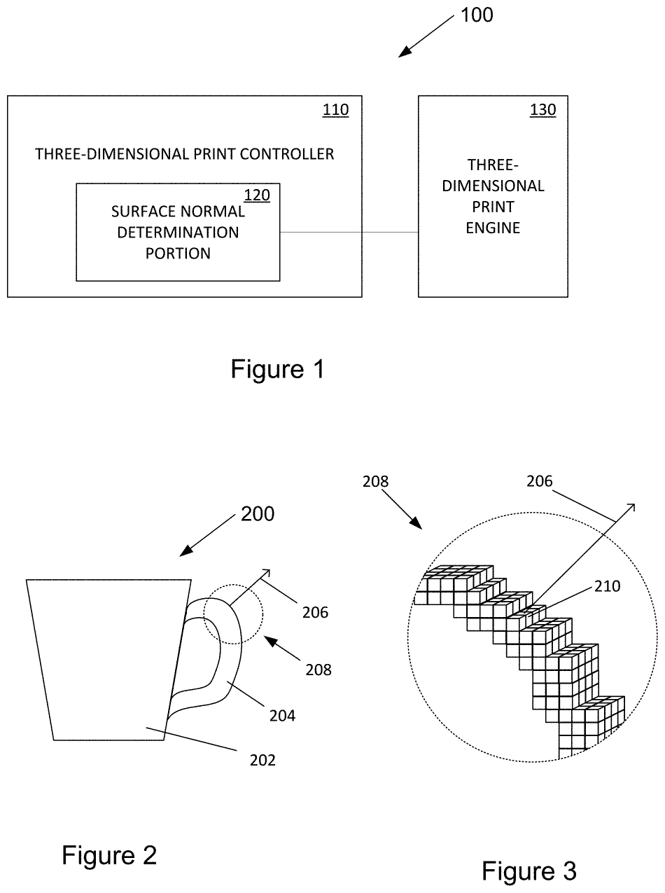

Referring now to the figures, FIG. 1 illustrates an example system 100 with determination of surface normal in a 3D object. The example system 100 of FIG. 1 includes a 3D print controller 110. The 3D print controller 110 may be implemented as hardware, software or firmware, for example. For example, the 3D print controller 110 may be a processor or a part thereof. The 3D print controller 110 is provided to control operation of a 3D print engine 130. The 3D print engine may be part of a 3D printing apparatus. In various examples, the 3D printing apparatus may use any of a variety of 3D printing technologies. Examples of such 3D-printing technologies include, without limitation, stereolithography (SLA), fused deposition modeling (FDM), selective laser sintering (SLS), and 3D binder jetting.

The 3D print engine 130 of the example system 100 of FIG. 1 may print a 3D print object based on voxel data that may be received from, for example, a user device. Voxel data may include location of voxels in the data file to form the 3D print object to be printed. Additional voxel data may include various parameters associated with each voxel, such as agents used, density or layer thickness, for example. In various examples of the voxel data, the voxels may have any of a variety of shapes. In one examples, the voxel data includes voxels having a cubic shape.

In the example system 100 of FIG. 1, the 3D print controller 110 is provided with a surface normal determination portion 120. The surface normal determination portion 120 is provided to determine a normal for at least one surface voxel of the 3D object. In various examples, the determination of the normal is based on the voxel data associated with the 3D object. The 3D print controller 110 causes the 3D print engine 130 to adjust at least one print parameter based on the normal for the at least one surface voxel determined by the surface normal determination portion 120. For example, based on the normal, the agents used, layer thickness or density of the surface voxel may be adjusted to compensate for variations in the print engine 130.

Referring now to FIG. 2, an example 3D object 200 is illustrated. In the example illustrated in FIG. 2, the example 3D object 200 is a mug 202 with a curved handle 204. FIG. 2 illustrates a surface normal vector 206 at one point of the curved handle 204. A voxel representation of a region 208 of the surface normal vector 206 is illustrated in detail in FIG. 3.

The voxel representation may be indicated in voxel data that is used to print the 3D object 200 by a 3D print engine. As noted above, the voxels may be of a variety of shapes and sizes. In the example of FIG. 3, the voxel representation of the 3D object 200 of FIG. 2 includes voxels having a cubic shape. FIG. 3 illustrates the surface normal 206 with respect to the voxel representation. As illustrated in FIG. 3, the surface normal 206 corresponds to a surface voxel 210.

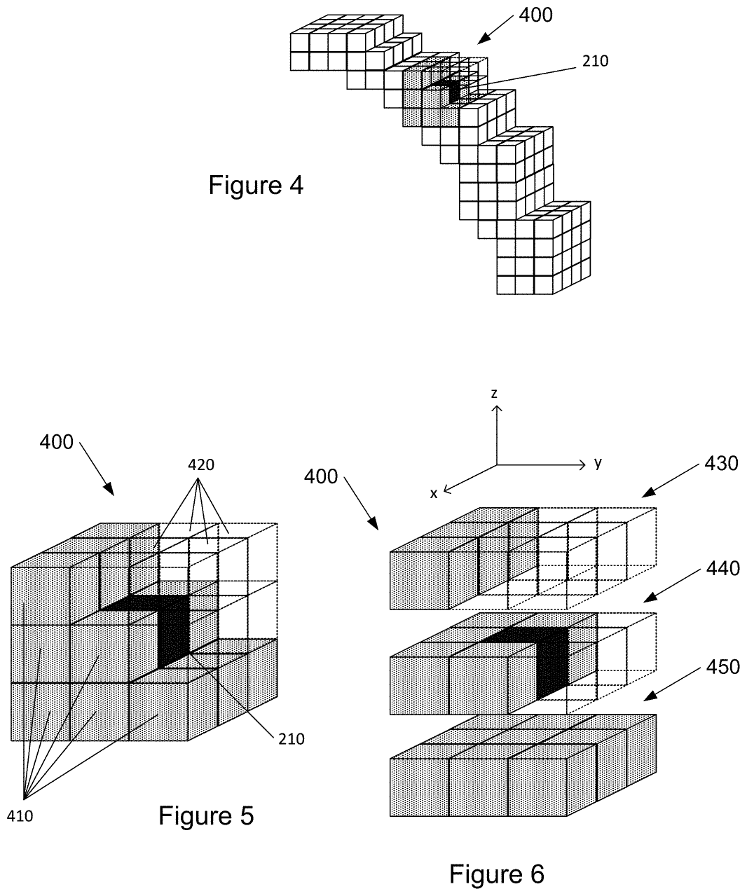

In various examples described herein, the determination of the surface normal 206 is based on a neighborhood of the surface voxel 210. In this regard, FIG. 4 illustrates the voxel representation of FIG. 3 with an example neighborhood 400 of the surface voxel 210, more clearly illustrated in FIG. 4. The example neighborhood 400 includes the surface voxel 210 (shown in black in FIG. 4) and a radius of a selected number of voxels in each direction.

Referring now to FIG. 5, a detailed representation of the surface voxel 210 and the example neighborhood 400 of the surface voxel 210 of FIG. 4. The example neighborhood 400 includes the surface voxel 210 and has a radius of one voxel in each direction. In other examples, the neighborhood may include any size radius. Further, in some examples, the radius may be different in the various directions.

FIG. 5 illustrates the example neighborhood 400 with a status of each voxel of the neighborhood indicated by shading of the voxel. For example, some voxels, such as voxels 410, are provided with a gray shading to indicate their status as present in the voxel representation of the 3D object. Conversely, other voxels, such as voxels 420, are provided with no shading to indicate their status as absent in the voxel representation of the 3D object.

In various examples, a look-up table may be generated or provided to indicate the status of each voxel. For example, a look-up table may be generated for the voxels of the voxel representation of the 3D object. In addition to voxels of the 3D object, the look-up table may include at least a limited amount of voxels around the 3D object to include, for example, a desired radius in each direction of the surface voxels of the 3D object. In some examples, the look-up table may include the status of each possible voxel in a print region of a 3D printer. Of course, a large look-up table may use a large amount of storage. Accordingly, the size of the look-up table may be traded off against memory availability.

For a 3D object, the look-up table may be populated with the status of each voxel covered in the look-up table. In one example, the look-up table is populated with a “1” for each voxel that is present in the 3D object and with a “0” for each voxel absent from the 3D object. Thus, the neighborhood 400 of FIGS. 4 and 5 may be encoded as a 27-bit word corresponding to the 27 voxels (the subject voxel 210 and the 26 neighboring voxels 410, 420), some of which may be present or absent in the object.

As noted above, the determination of the surface normal is based on a neighborhood of the surface voxel. In this regard, referring to the example of FIG. 5, the surface normal of the surface voxel 210 may be determined based on the neighborhood 400 of the surface voxel 210. Using the status of the voxels of the neighborhood (present or absent), the surface normal of the subject voxel 210 may be determined or estimated.

In one example, as illustrated in the example of FIG. 5, the neighborhood includes the subject voxel 210 and a radius, or distance, of one voxel in each direction. Thus, the look-up table includes 27 entries for the subject voxel 210 and 26 surrounding voxels 410, 420. Of course, if the neighborhood has a larger radius, the number of entries in the look-up table will increase correspondingly. As the radius (and the number of entries in the look-up table) of the neighborhood is increased, the accuracy of the surface normal increases with a corresponding increase in computational complexity.

In some examples, in order to make handling of the neighborhood more manageable and to simplify computation, the neighborhood may be divided into two or more sub-neighborhoods. For example, FIG. 6 illustrates the example neighborhood 400 of FIGS. 4 and 5 divided into examples sub-neighborhoods 430, 440, 450. In the example of FIG. 6, a look-up table for each sub-neighborhood 430, 440, 450. Thus, the sub-neighborhoods 430, 440, 450 may be encoded as three 9-bit words.

In one example, a normal triplet (x, y, z) can be determined for each sub-neighborhood 430, 440, 450, with the x-y-z directions as indicated in FIG. 6. In the example of FIG. 6, the normal triplets for the sub-neighborhoods 430, 440, 450 may be calculated as follows. For the top sub-neighborhood 430, the sub-neighborhood 430 may be encoded as 111|000|000, where a “1” is indicative of a present voxel and a “0” is indicative of an absent voxel. In various examples, the encoding may be performed in various forms, such as hexadecimal. Thus, the sub-neighborhood 430 may be encoded as 1x1c0 (hex). A partial look-up table for the sub-neighborhood 430 may be as follows:

TABLE 1

| Input Value | Output |
|---|---|
| 0 | 0, 0, 0 |
| . . . | |
| 0x1c0 | 0, +1.862, −1.862 |
| . . . | |
| 0x1ff | 0, 0, −6.138 |

For the subject voxel 210, the above lookup table for the encoded sub-neighborhood 430 yields the triplet [0, +1.862, −1.862]. Thus, the three present voxels in the top sub-neighborhood influence the final determination or estimation of the surface normal by a weighted value that is at a 45-degree angle in the Y-Z plane.

Similar weightings may be calculated for the middle sub-neighborhood 440 and the bottom sub-neighborhood 450. For the middle sub-neighborhood 440, the sub-neighborhood 440 may be encoded as 111|111|000 or 0x1f8 (hex), and a partial look-up table may be as follows:

TABLE 2

| Input Value | Output |
|---|---|
| 0 | 0, 0, 0 |
| . . . | |
| 0x1f8 | 0, +2.414, 0 |
| . . . | |
| 0x1ff | 0, 0, 0 |

The look-up table for the sub-neighborhood 440 yields a triplet of [0, 2.414, 0]. Thus, the weighting is completely in the Y direction. For the bottom sub-neighborhood 450, the sub-neighborhood 450 may be encoded as 111|111|111 or 0x1ff (hex), yielding a look-up triplet of [0, 0, 6.138], or a weighting completely in the Z direction. The vector sum of the weighted results of the three sub-neighborhoods 730, 740, 750 yields an estimated resulting normal vector of [0, 4.276, 4.276]. The resulting normal vector may be normalized to a unit vector of [0, 0.707, 0.707]. Thus, in the example of FIGS. 4-6, the unit vector for the surface normal for the voxel 210 is a vector that is at 45 degree angle in the YZ plane in the positive Y and positive Z directions. Of course, the above-described calculations are merely an example for the example described in FIGS. 4-6. Similar calculations may be used to determine a surface normal for other surface voxels. Further, the precision of the estimated normal vector may depend on various factors, such as the size of the neighborhood and the number of sub-neighborhoods, for example.

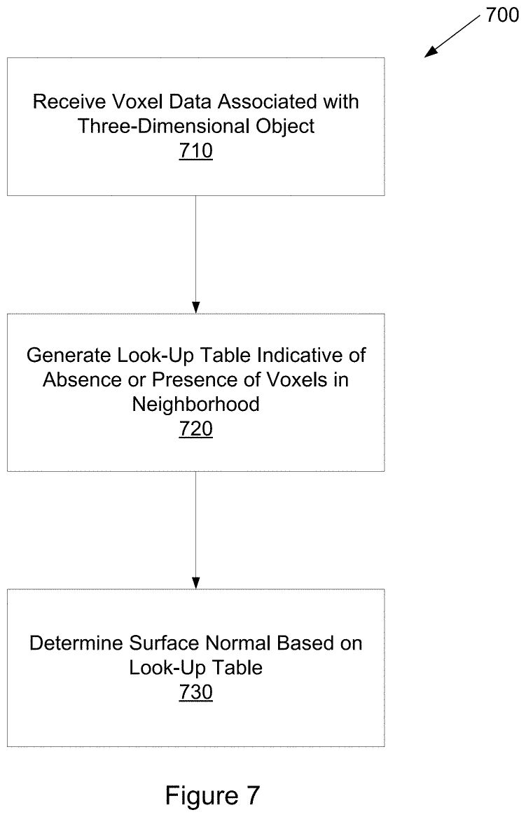

Referring now to FIG. 7, a flow chart illustrates an example method 700 for determining a surface normal from voxel data. The example method 700 may be executed by, for example, the 3D print controller 110 or the surface normal determination portion 120 of the example system 100 of FIG. 1. The example method 700 includes receiving voxel data associated with a three-dimensional (3D) object (block 710). In various examples, the voxel data may be received from a user, a user device or an input file, for example. As noted above, the voxel data may include voxels of various shapes (e.g., cubic shape) and sizes.

The example method may further include generating a look-up table for a surface voxel (block 720). As described above, the look-up table may be indicative of absence or presence of voxels in a neighborhood of the surface voxel. For example, the look-up table may indicate whether a voxel in a neighborhood of a subject surface voxel is present in or absent from the voxel representation of the 3D object. In various examples, the look-up table may be used to encode the neighborhood as a 27-bit word for a neighborhood have a radius of one voxel in each direction.

Referring again to the example method 700 of FIG. 7, a surface normal of the surface voxel may then be determined based on the look-up table (block 730). For example, as described above with reference to FIGS. 5 and 6, the voxel data represented in the look-up table of a neighborhood of a surface voxel may be used to determine a surface normal of the surface voxel.

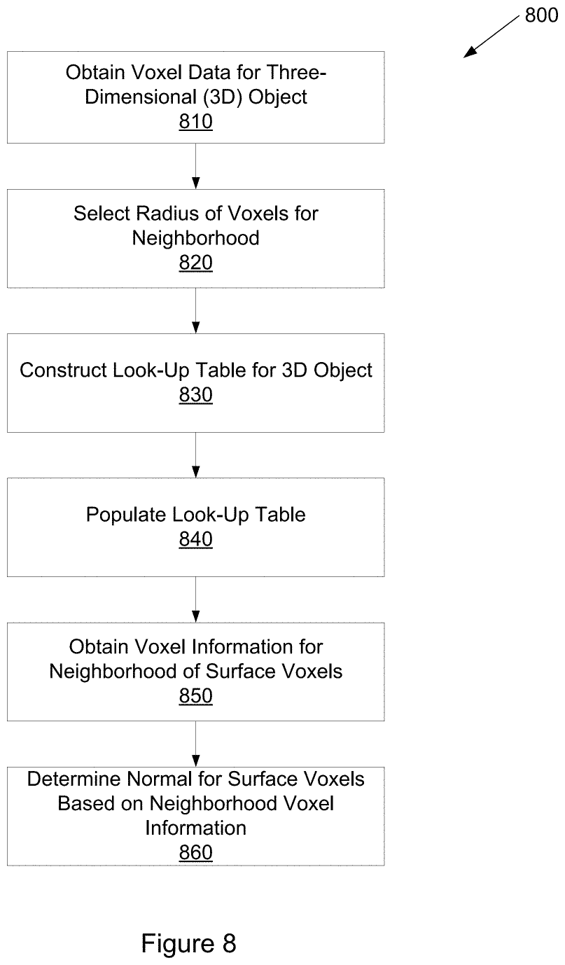

Referring now to FIG. 8, a flow chart illustrates another example method 800 for determining a surface normal from voxel data. Similar to the example method 700 of FIG. 7, the example method 800 of FIG. 8 may be executed by, for example, the 3D print controller 110 or the surface normal determination portion 120 of the example system 100 of FIG. 1. The example method 800 includes obtaining voxel data associated with a three-dimensional (3D) object (block 810). In various examples, the voxel data may be received from a user, a user device or an input file, for example. As noted above, the voxel data may include voxels of various shapes (e.g., cubic shape) and sizes.

At block 820, a radius of voxels is selected for use in neighborhoods for the 3D object. As noted above, in one example, a radius of one voxel in each direction is selected. In some examples, the radius may be two or more voxels in each direction. In some examples, the radius may be different in at least one direction from the other directions.

At block 830, a look-up table is constructed for the 3D object. In one example, the look-up table includes voxels of the 3D object and those in neighborhoods of each surface voxel. The look-up table may then be populated (block 840). As noted above, the look-up table may be populated with “1” for each voxel that is present in the voxel representation of the 3D object and with “0” for each voxel that is absent from the voxel representation of the 3D object.

At block 850, for at least one surface voxel, voxel information (e.g., status of the voxel) is obtained for each voxel in the neighborhood of the surface voxel. As noted above, the neighborhood of the surface voxel may be encoded as a word that has a length which corresponds to the number of voxels in the neighborhood.

At block 860, the surface normal for the surface voxel is determined based on the neighborhood voxel information. As described above with reference to FIG. 6, the surface normal may be determined based on the absence or presence of voxels in the neighborhood of the surface voxel.

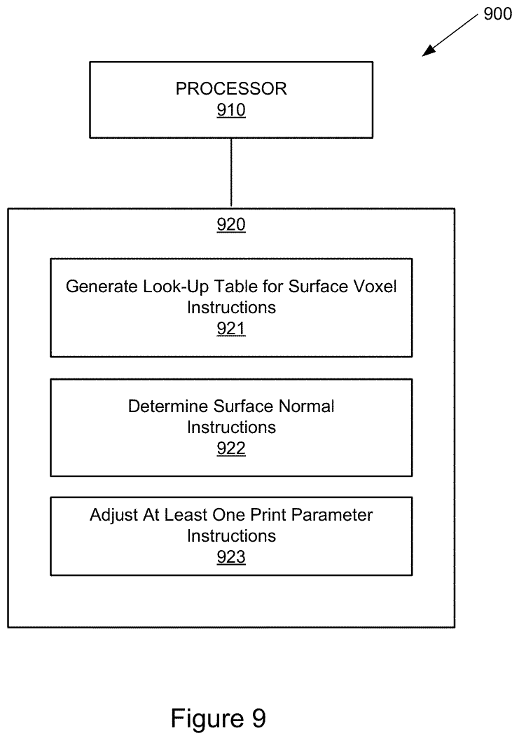

Referring now to FIG. 9, a block diagram of an example system is illustrated with a non-transitory computer-readable storage medium including instructions executable by a processor for surface normal determination. The system 900 includes a processor 910 and a non-transitory computer-readable storage medium 920. The computer-readable storage medium 920 includes example instructions 921-923 executable by the processor 910 to perform various functionalities described herein. In various examples, the non-transitory computer-readable storage medium 920 may be any of a variety of storage devices including, but not limited to, a random access memory (RAM) a dynamic RAM (DRAM), static RAM (SRAM), flash memory, read-only memory (ROM), programmable ROM (PROM), electrically erasable PROM (EEPROM), or the like. In various examples, the processor 910 may be a general purpose processor, special purpose logic, or the like.

The example instructions include generate look-up table for surface voxel instructions 921. In various examples, the look-up table is generated from voxel data of a 3D object and includes a status of voxels in a neighborhood of a surface voxel. As noted above, the status of voxels indicates whether the voxel is present or absent in the voxel representation of the 3D object. For example, as noted above, a look-up table for a 3D object may be generate to indicate the presence or absence of voxels in at least the 3D object and the neighborhood of surface voxels.

The example instructions further include determine surface normal instructions 922. In various examples, the surface normal for the surface voxel is based on the status of voxels in the neighborhood indicated in the look-up table, as illustrated, for example, in the example of FIG. 6 above.

The example instructions further includes adjust at least one print parameter instructions 923. For example, various parameters for a 3D print engine may be adjusted based on the surface normal. Such parameters may include a color adjustment (e.g., the agent used to adjust color via color properties or thermal properties), layer thickness adjustment or a density adjustment, for example. In one example, the 3D print engine may print an accurate color when the surface normal is in the z direction. Without compensation or adjustment, the color may become inaccurate as the normal deviates from the z direction. In this regard, depending on the direction of the normal, the print engine may apply the appropriate compensation.

Thus, various examples allow determination of a normal direction for a 3D object based on the voxel data of the 3D object without additional information. The determination of the normal allows compensation or adjustment of various print parameters of a 3D printer.

Software implementations of various examples can be accomplished with standard programming techniques with rule-based logic and other logic to accomplish various database searching steps or processes, correlation steps or processes, comparison steps or processes and decision steps or processes.

The foregoing description of various examples has been presented for purposes of illustration and description. The foregoing description is not intended to be exhaustive or limiting to the examples disclosed, and modifications and variations are possible in light of the above teachings or may be acquired from practice of various examples. The examples discussed herein were chosen and described in order to explain the principles and the nature of various examples of the present disclosure and its practical application to enable one skilled in the art to utilize the present disclosure in various examples and with various modifications as are suited to the particular use contemplated. The features of the examples described herein may be combined in all possible combinations of methods, apparatus, modules, systems, and computer program products.

It is also noted herein that while the above describes examples, these descriptions should not be viewed in a limiting sense. Rather, there are several variations and modifications which may be made without departing from the scope as defined in the appended claims.

What is claimed is:

1. A system, comprising:
a three-dimensional (3D) print engine to produce a 3D object based on voxel data associated with the 3D object; and
a 3D print controller to control operation of the 3D print engine, the 3D print controller having a surface normal determination portion,
wherein the surface normal determination portion is to determine a normal for at least one surface voxel of the 3D object, the determination of the normal being based on the voxel data, and
wherein the 3D print controller is to cause the 3D print engine to adjust at least one print parameter based on the normal for the at least one surface voxel determined by the surface normal determination portion.

2. The system of claim 1, wherein the surface normal determination portion is to determine the normal based on a neighborhood of the at least one surface voxel.

3. The system of claim 2, wherein the surface normal determination portion is to determine the normal using a look-up table indicative of presence or absence of voxels in the neighborhood.

4. The system of claim 2, wherein the neighborhood has a radius of one voxel in each direction.

5. The system of claim 2, wherein the neighborhood has a radius of two or more voxels in at least one direction.

6. The system of claim 1, wherein the at least one print parameter is selected from an agent used, layer thickness or density.

7. A method, comprising:
receiving voxel data associated with a three-dimensional (3D) object;
generating a look-up table for a surface voxel, the look-up table being indicative of absence or presence of voxels in a neighborhood of the surface voxel; and
determining a surface normal of the surface voxel based on the look-up table.

8. The method of claim 7, wherein the neighborhood has a radius of one voxel in each direction.

9. The method of claim 7, wherein the neighborhood has a radius of two or more voxels in at least one direction.

10. The method of claim 7, further comprising:
adjusting at least one print parameter for a 3D print engine based on the surface normal.

11. The method of claim 10, wherein the at least one print parameter is selected from an agent used, layer thickness or density.

12. A non-transitory computer-readable storage medium encoded with instructions executable by a processor of a computing system, the computer-readable storage medium comprising instructions to:
generate a look-up table for a surface voxel from voxel data of a three-dimensional (3D) object, the look-up table indicating a status of voxels in a neighborhood of the surface voxel, the status being either present or absent;
determine a surface normal for the surface voxel based on the status of voxels in the neighborhood indicated in the look-up table; and
adjust at least one print parameter for a 3D print engine based on the surface normal.

13. The non-transitory computer-readable storage medium of claim 12, wherein the neighborhood has a radius of one voxel in each direction.

14. The non-transitory computer-readable storage medium of claim 12, wherein the neighborhood has a radius of two or more voxels in at least one direction.

15. The non-transitory computer-readable storage medium of claim 12, wherein the at least one print parameter is selected from agent used, layer thickness or density.
